(19) United States
(12) Patent Application Publication
(10) Pub. No.: US 2010/0230680 A1
(43) Pub. Date: Sep. 16, 2010

(54) LIQUID CRYSTAL DISPLAY DEVICE INCLUDING COMMON ELECTRODE AND REFERENCE ELECTRODE

(75) Inventors: Dong-Gi SEONG, Seongnam-si (KR); Joo-Seok YEOM, Gwacheon-si (KR); Youn-Hak JEONG, Cheonan-si (KR); Keun-Chan OH, Cheonan-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/618,491

(22) Filed: Nov. 13, 2009

(30) Foreign Application Priority Data
Mar. 13, 2009 (KR) 10-2009-0021415

(51) Int. Cl. H01L 33/00

(52) U.S. Cl. 257/59; 257/72; 257/E33.053; 257/E33.013

(57) ABSTRACT

A liquid crystal display includes; a first substrate, a gate line disposed on the first substrate, a data line intersecting the gate line, a thin film transistor connected to the gate line and the data line, a pixel electrode connected to the thin film transistor, an interlayer insulating layer disposed on the pixel electrode, a common electrode disposed on the interlayer insulating layer and including a plurality of electrically connected common electrode lines extending substantially parallel to each other, a second substrate disposed substantially opposite to the first substrate, a reference electrode disposed on substantially an entire surface of the second substrate, and a liquid crystal layer disposed between the first substrate and the second substrate, and having negative dielectric anisotropy.

This application claims priority to Korean Patent Application No. 10-2009-0021415, filed on Mar. 13, 2009, and all the benefits accruing therefrom under 35 U.S.C. §119, the contents of which in its entirety is herein incorporated by reference.

### BACKGROUND OF THE INVENTION

(a) Field of the Invention

The present invention relates to a liquid crystal display.

(b) Description of the Related Art

A liquid crystal display (“LCD”) is one of the most widely used types of flat panel displays and has various merits such as its light weight and thin formation, the power consumption is relatively small, and a relatively small amount of harmful electromagnetic waves are generated thereby.

Generally, the typical LCD includes an array substrate, a color filter substrate, and a liquid crystal layer. The color filter substrate is provided with a common electrode that is applied with a common voltage, and the array substrate is applied with a pixel voltage having a different voltage level from the common voltage. Accordingly, the voltage difference between the common voltage and the pixel voltage forms an electromagnetic field between the array substrate and the color filter substrate, and the electromagnetic field rotates an orientation of liquid crystal molecules included in the liquid crystal layer.

Accordingly, a rotation ratio, e.g., a degree of rotation, of the liquid crystal molecules is changed according to the magnitude of the electromagnetic field. That is, the rotation ratio of the liquid crystal molecules is increased as the magnitude of the electromagnetic field is increased, and as a result the transmittance of the LCD is increased and the response speed is improved with the application of larger and larger electromagnetic fields.

However, the typical LCD has lower lateral visibility than front visibility, and liquid crystal arrangements and driving methods of various types have been developed to solve such a drawback. To realize a wide viewing angle, a patterned vertical alignment (“PVA”) mode applied with a cutout to divide domains of the liquid crystal display having a vertical alignment (“VA”) mode, and an in-plane switching (“IPS”) mode applied with a lateral electric field method, have been proposed.

However, the PVA mode may generate texture or afterimages, and still has a limit in realizing a complete wide viewing angle. Also, in the IPS, the common electrode decreases the aperture ratio of the LCD such that the luminance is relatively low, and accordingly a backlight with high luminance, and the associated drawbacks thereof, is typically be applied.

As a technique for simultaneously realizing the wide viewing angle and the high luminance, a plane to line switching (“PLS”) mode applied with a lateral electric field like the IPS mode has been receiving increased attention.

### BRIEF SUMMARY OF THE INVENTION

The present invention increases transmittance and improves response speed of a liquid crystal display.

An exemplary embodiment of a liquid crystal display (“LCD”) according to an the present invention includes; a first substrate, a gate line disposed on the first substrate, a data line intersecting the gate line, a thin film transistor connected to the gate line and the data line, a pixel electrode connected to the thin film transistor, an interlayer insulating layer disposed on the pixel electrode, a common electrode disposed on the interlayer insulating layer and including a plurality of electrically connected common electrode lines extending substantially parallel to each other, a second substrate disposed substantially opposite to the first substrate, a reference electrode disposed on substantially an entire surface of the second substrate, and a liquid crystal layer disposed between the first substrate and the second substrate and having negative dielectric anisotropy.

In one exemplary embodiment, the pixel electrode may be vertically aligned with the plurality of common electrode lines, and may form a substantially continuous surface throughout an area wherein the pixel electrode and the plurality of common electrode lines are vertically aligned.

In one exemplary embodiment, an image signal voltage applied to the pixel electrode and a common voltage applied to the common electrode may be inverted with respect to a reference voltage applied to the reference electrode per an individual frame.

In one exemplary embodiment, the image signal voltage and the common voltage may have opposite polarities with respect to the reference voltage.

In one exemplary embodiment, the thin film transistor may include; a gate electrode connected to the gate line, a gate insulating layer disposed on the gate electrode, a semiconductor layer disposed on the gate insulating layer, a source electrode connected to the data line and vertically aligned with the gate electrode, and a drain electrode disposed substantially opposite to the source electrode with respect to the gate electrode, and a passivation layer disposed on the thin film transistor and having a contact hole for connecting the pixel electrode to the drain electrode.

In one exemplary embodiment, a common electrode pad connected to an end of the common electrode may be further included, and the common electrode pad may transmit a signal applied from an external driving device to the common electrode.

In one exemplary embodiment, the common electrode may be extended in a direction substantially parallel to a direction of extension of the data line, intersecting the gate line.

In one exemplary embodiment, a blocking film disposed between the gate line and the common electrode may be further included.

In one exemplary embodiment, the blocking film may be made of one of an organic layer, and an electrically floating conductor. In one exemplary embodiment, the blocking film may be disposed on a same layer as the data line.

In one exemplary embodiment, the common electrode may further include a connecting member which connects the plurality of common electrode, the common electrode having an island shape within an individual pixel.

In one exemplary embodiment, a common electrode pad connected to an end of the common electrode may be further included, and the common electrode pad may transmit a signal applied from an external driving device to the common electrode.

In one exemplary embodiment, the liquid crystal layer may have dielectric anisotropy of about −2 to about −3.5, and rotation viscosity of about 50 mPas to about 120 mPas.

Another exemplary embodiment of an LCD according to the present invention includes; a first substrate, a gate line disposed on the first substrate, a first data line and a second data line intersecting the gate line, and respectively transmitting a first data voltage and a second data voltage, a first thin film transistor connected to the gate line and the first data line, a second thin film transistor connected to the gate line and the second data line, a pixel electrode connected to the first thin film transistor, an interlayer insulating layer disposed on the pixel electrode, a common electrode disposed on the interlayer insulating layer, connected to the second thin film transistor, and having a plurality of branch lines electrically connected to each other and extending substantially parallel to each other, a second substrate disposed substantially opposite to the first substrate, a reference electrode disposed on substantially an entire surface of the second substrate, and a liquid crystal layer disposed between the first substrate and the second substrate.

In one exemplary embodiment, the pixel electrode may be vertically aligned with the plurality of branch lines, and may form a substantially continuous surface throughout an area wherein the pixel electrode and the plurality of branch lines are vertically aligned.

In one exemplary embodiment, an image signal voltage applied to the pixel electrode and a common voltage applied to the common electrode may be inverted with respect to a reference voltage applied to the reference electrode per an individual frame.

In one exemplary embodiment, the image signal voltage and the common voltage may have substantially opposite polarities with respect to the reference voltage.

In one exemplary embodiment, the pixel electrode may be applied with a first data voltage and the common electrode may be applied with a second data voltage, and absolute values of the first data voltage and the second data voltage may be substantially the same.

In one exemplary embodiment, the pixel electrode may be applied with a first data voltage and the common electrode may be applied with a second data voltage, the first data voltage and the second data voltage may have opposite polarities with respect to the reference voltage, and the absolute values of the first data voltage and the second data voltage may be substantially the same.

In one exemplary embodiment, according to the present invention, a liquid crystal layer having negative dielectric anisotropy is used, and different signals are applied to the pixel electrode and the common electrode such that the transmittance and the response speed may be simultaneously improved.

### BRIEF DESCRIPTION OF THE DRAWINGS

FIG. 1 is a top plan layout view of an exemplary embodiment of a liquid crystal display (“LCD”) according to the present invention.

FIG. 2 is a cross-sectional view taken along line II-II′ shown in FIG. 1.

FIG. 3 is a cross-sectional view taken along line III-III′ shown in FIG. 1.

FIG. 4 is a top plan layout view of another exemplary embodiment of an LCD according to the present invention.

FIG. 5 is a cross-sectional view taken along line V-V′ shown in FIG. 4.

FIG. 6 is a top plan layout view of another exemplary embodiment of an LCD according to the present invention.

FIG. 7 is a cross-sectional view taken along line VII-VII′ and line VII′-VII″ shown in FIG. 6.

FIG. 8 is a waveform diagram showing an exemplary embodiment of a driving method of an exemplary embodiment of an LCD of the present invention.

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein. All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

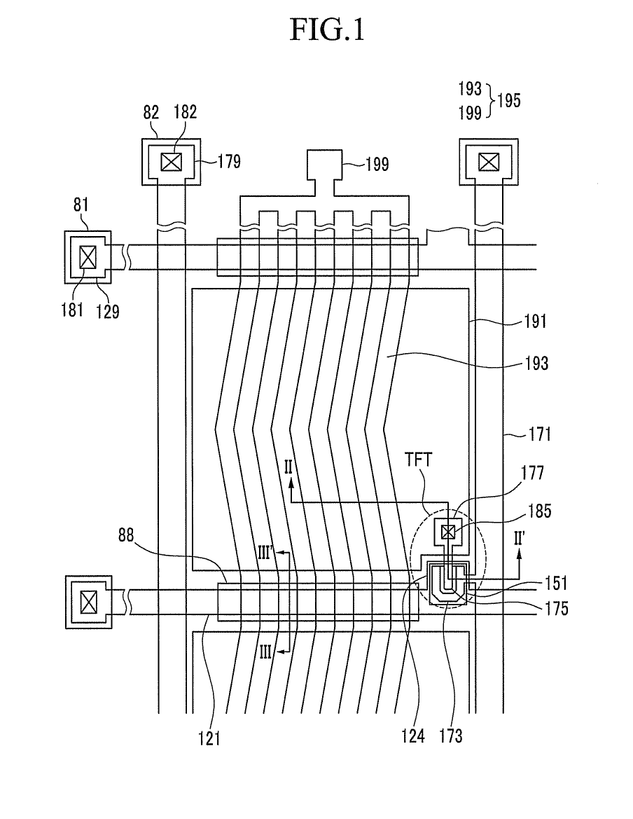

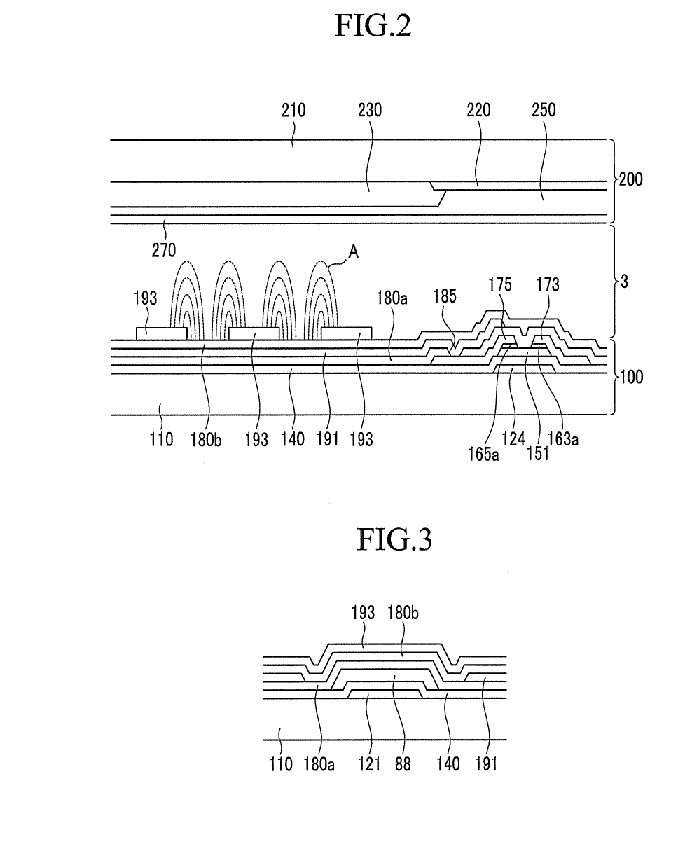

FIG. 1 is a top plan layout view of an exemplary embodiment of a liquid crystal display (“LCD”) according to the present invention. FIG. 2 is a cross-sectional view taken along line II-II′ shown in FIG. 1. FIG. 3 is a cross-sectional view taken along line III-III′ shown in FIG. 1.

Referring to FIG. 1 and FIG. 2, an exemplary embodiment of an LCD according to the present invention includes a first display panel 100, a second display panel 200, and a liquid crystal layer 3 interposed between the two display panels 100 and 200. In the present exemplary embodiment, the liquid crystal layer 3 may have negative dielectric anisotropy.

The first display panel 100 includes a first insulation substrate 110, a pixel electrode 191, and a common electrode 195 disposed on, e.g., vertically aligned with, the pixel electrode 191 with an interlayer insulating layer 180b disposed therebetween. The pixel electrode 191 is formed with an island shape within each of a plurality of pixel areas that include an area bounded by gate lines 121 and data lines 171 that are intersecting the gate lines 121. The common electrode 195 may be continuously formed along a column direction in the pixel areas. The common electrode 195 includes a plurality of common electrode lines 193 which are connected to each other and which extend substantially parallel with each other. The data lines 171 may be formed in a zigzag shape along a longitudinal direction.

In one exemplary embodiment, the pixel electrode 191 is formed to have a plane shape occupying most of the pixel area. Accordingly, each pixel electrode 191 overlaps a plurality of common electrode lines 193, and forms a substantially continuous surface in an area vertically aligned with the plurality of common electrode lines 193.

The interlayer insulating layer 180b is formed with a predetermined thickness on the pixel electrodes 191, and the plurality of common electrode lines 193, which are separated from each other with a predetermined interval, are formed on the interlayer insulating layer 180b. The plurality of common electrode lines 193 are connected to each other in each pixel area, thereby forming the common electrode. Here, the pixel electrode 191 overlaps the common electrode line 193 with the interlayer insulating layer 180b disposed therebetween. In one exemplary embodiment the interlayer insulating layer 180b is thick enough to prevent electrical shorting between the common electrode line 193 and the pixel electrode 191.

In one exemplary embodiment, the pixel electrode 191 of the first display panel 100 may be provided with a pixel voltage from the outside, for example data voltages, and the common electrode 195 may be provided with a common voltage from the outside. Accordingly, a horizontal electric field “A” may be formed by a potential difference between the data voltage and the common voltage between the pixel electrode 191 and the common electrode 195 in order to rotate liquid crystal molecules of the liquid crystal layer 3.

A backlight assembly (not shown) may be disposed under the first display panel 100 in order to provide light to the LCD. The light provided from the backlight assembly may be transmitted or blocked by a rotation of the liquid crystal molecules of the liquid crystal layer 3 due to the horizontal electric field A.

An exemplary embodiment of the second display panel 200 includes a second insulation substrate 210, a color filter 230, a black matrix 220, an overcoat 250, and a reference electrode 270. Alternative exemplary embodiments include configurations wherein the overcoat 250 may be omitted, and the color filter 230 and the black matrix 220 may be formed in the first display panel 100 or omitted.

In the present exemplary embodiment, the reference electrode 270 may be formed on the surface opposing the first display panel 100 of the two surfaces of the second insulation substrate 210, when the first display panel 100 and the second display panel 200 are contacted to each other. In one exemplary embodiment, the reference electrode 270 may be provided with a uniform voltage.

Next, an exemplary embodiment of an LCD according to the present invention will be described in detail with reference to FIG. 1 to FIG. 3.

A plurality of gate lines 121 are formed on an insulation substrate 110, exemplary embodiments of which may be made of transparent glass, plastic, or other materials having similar characteristics. Each gate line 121 transfers a gate signal and is mainly extended in a substantially transverse direction. Each gate line 121 includes a plurality of gate electrodes 124 that are protruded upward therefrom, and a wide end part 129 for connecting to other layers or an external driving circuit. Exemplary embodiments include configurations wherein the end part 129 is omitted. Exemplary embodiments of a gate driving circuit (not shown) that generates a gate signal may be mounted on a flexible printed circuit film (not shown) that is attached on the first insulation substrate 110 in a form of an integrated circuit (“IC”) chip, directly mounted on the first insulation substrate 110, or integrated in the first insulation substrate 110. When the gate driving circuit is integrated in the substrate 110, the gate line 121 is extended to directly connect to the circuit. Alternative exemplary embodiments include alternative methods of connected the gate driving circuit to the plurality of gate lines 121.

Exemplary embodiments of the gate line 121 and the common electrode lines 193 may be made of aluminum-containing metals such as aluminum (Al) or an aluminum alloy, silver-containing metals such as silver (Ag) or a silver alloy, copper-containing metals such as copper (Cu) or a copper alloy, molybdenum-containing metals such as molybdenum (Mo) or a molybdenum alloy, chromium (Cr), thallium (Ta), titanium (Ti), and other materials having similar characteristics. However, the gate lines 121 and/or common electrode lines 193 may have a multi-layered structure including two or more conductive layers (not shown) that have different physical properties. One conductive layer among the two or more conductive layers may be made of metals having low resistivity, exemplary embodiments of which include aluminum metals, silver metals, copper metals, and other similar materials, in order to reduce a signal delay or a voltage drop. One of the other conductive layers may be made of a material such as a molybdenum metal, chromium, thallium, titanium, or other similar materials, that has excellent physical, chemical, and electrical contact characteristics with other materials, specific exemplary embodiments of which include indium tin oxide (“ITO”) and indium zinc oxide (“IZO”). A good example of such a combination may include a chromium lower layer and an aluminum (alloy) upper layer, and an aluminum (alloy) lower layer and a molybdenum (alloy) upper layer. However, the gate line 121 and the common electrode lines 193 may made of various metals or electrical conductors, in addition to the above-described materials.

Side surfaces of the gate line 121 and the common electrode lines 193 are inclined with respect to a surface of the substrate 110, and in one exemplary embodiment an inclination angle thereof may be from about 30° to about 80°.

A gate insulating layer 140, exemplary embodiments of which may be made of silicon nitride (SiNx), silicon oxide (SiOx), or other similar materials is formed on the gate line 121. The gate insulating layer 140 prevents an electrical short between the gate lines 121, and has a function of insulating the gate lines 121 from a conductive thin film formed thereon. A plurality of semiconductor islands 151, exemplary embodiments of which may be made of hydrogenated amorphous silicon (a-Si), polysilicon, or other similar materials are formed on the gate insulating layer 140. Each semiconductor island 151 may be positioned on an individual gate electrode 124.

A plurality of ohmic contacts 163a and 165a are formed on the semiconductor islands 151. Exemplary embodiments of the ohmic contacts 163a and 165a may be made of a material such as n+hydrogenated amorphous silicon in which an n-type impurity such as phosphorus is doped with high concentration, or of silicide. The ohmic contacts 163a and 165a are formed in pairs and are disposed on the semiconductor islands 151.

In one exemplary embodiment, side surfaces of the semiconductor islands 151 and the ohmic contacts 163a and 165a may also be inclined with respect to a surface of the substrate 110, and an inclination angle thereof may be about 30° to about 80°.

A plurality of data lines 171 and a plurality of drain electrodes 175 are formed on the ohmic contacts 163a and 165a and the gate insulating layer 140. The data lines 171 transfer a data signal and are mainly extended in a longitudinal direction, thereby being substantially perpendicular to the gate lines 121. Each data line 171 includes a plurality of source electrodes 173 that extend toward the gate electrode 124, and a wide end part 179 for connecting to other layers or an external driving circuit. Exemplary embodiments include configurations wherein the wide end part 179 may be omitted. A data driving circuit (not shown) that generates a data signal may be mounted on a flexible printed circuit film (“FPC”) (not shown) that is attached on the substrate 110, directly mounted on the substrate 110, or integrated in the substrate 110. When the data driving circuit is integrated in the substrate 110, the data line 171 can be extended to directly connect to the circuit. Alternative exemplary embodiments include alternative methods of connected the data driving circuit to the date lines 171.

The drain electrode 175 is separated from the data line 171 and faces the source electrode 173 with respect to the gate electrode 124. Each of the drain electrodes 175 includes one end portion 177 having a wide area and the other end portion having a bar shape, and the portions of the drain electrodes 175 with the bar shape are enclosed on at least three sides by the source electrodes 173 with a “U” shape, respectively.

One gate electrode 124, one source electrode 173, one drain electrode 175, and the semiconductor island 151 constitute one thin film transistor (“TFT”), and a channel of the TFT is formed in the semiconductor island 151 between the source electrode 173 and the drain electrode 175.

In one exemplary embodiment, the data line 171 and the drain electrode 175 are made of a refractory metal such as molybdenum, chromium, thallium, and titanium, or their alloys. Exemplary embodiments include configurations wherein the data line 171 and the drain electrode 175 have a multi-layered structure including a refractory metal layer (not shown) and a low resistance conductive layer (not shown). Exemplary embodiments of the multi-layered structures include, for example, a dual layer of a chromium or molybdenum (alloy) lower layer and an aluminum (alloy) upper layer, and a triple layer of a molybdenum (alloy) lower layer, an aluminum (alloy) intermediate layer, and a molybdenum (alloy) upper layer. However, exemplary embodiments of the data lines 171 and the drain electrodes 175 may be made of various metals or electric conductors.

In the present exemplary embodiment, the ohmic contacts 163 and 165 are disposed only between the semiconductor islands 151 and the data line 171 and the drain electrode 175, and reduce contact resistance between the semiconductor islands 151 and the data line 171 and the drain electrode 175. The semiconductor island 151 includes portions that are exposed without being covered by the data line 171 and the drain electrode 175, and a portion that is exposed between the source electrode 173 and the drain electrode 175.

A passivation layer 180a is formed on the data line 171, the drain electrode 175, and the gate insulating layer 140. Exemplary embodiments include configurations wherein the passivation layer 180a may be made of inorganic insulator, and exemplary embodiments of the inorganic insulators include, for example, silicon nitride and silicon oxide. In one exemplary embodiment, the organic insulator may have photosensitivity, and the dielectric constant thereof may be less than about 4.0. However, alternative exemplary embodiments include configurations wherein the passivation layer 180a can have a dual-layer structure having a lower inorganic layer and an upper organic layer in order to prevent damage of the exposed portions of the semiconductor 151 while having excellent insulating characteristics of the organic layer.

The passivation layer 180a has a plurality of contact holes 185 exposing the drain electrodes 175.

The plurality of pixel electrodes 191 are formed on the passivation layer 180a. The pixel electrodes 191 may be made of a transparent conductive material such as ITO or IZO.

The pixel electrodes 191 are physically and electrically connected to the drain electrodes 175 through the contact holes 185, and respectively receive data voltages from the drain electrodes 175. The pixel electrodes 191 are formed with the island shape as described above in a plurality of pixel areas which include an area bound by the gate lines 121 and the data lines 171.

The interlayer insulating layer 180b is formed on the pixel electrodes 191. Exemplary embodiments include configurations wherein the interlayer insulating layer 180b may be formed on substantially the entire surface of the first insulation substrate 110. The interlayer insulating layer 180b and the passivation layer 180a have a plurality of contact holes 182 exposing the end portions 179 of the data lines 171, and the interlayer insulating layer 180b, the passivation layer 180a, and the gate insulating layer 140 have a plurality of contact holes 181 exposing the end portions 129 of the gate lines 121.

The common electrode 195 including the plurality of common electrode lines 193 is formed on the interlayer insulating layer 180b. The common electrode lines 193 are separated from each other, and are disposed substantially parallel to each other. The common electrode lines 193 are separated from each other throughout a majority of their length, however they may be connected to each other on one end of the common electrode 195. Accordingly, a plurality of common electrode lines 193 may be applied with substantially the same signal. As discussed above, exemplary embodiments of the common electrode 195 may be made of a transparent conductive material such as ITO or IZO.

Also, in the exemplary embodiment wherein the gate lines 121 and data lines 171 are not directly connected to a gate driver and/or a data driver, respectively, a plurality of contact assistants 81 and 82 are formed on the interlayer insulating layer 180b. The contact assistants 81 and 82 may be made of the transparent conductive material such as ITO or IZO similar to the common electrode 195. The contact assistants 81 are connected to the end portions 129 of the gate lines through the contact holes 181, and the contact assistants 82 are connected to the end portions 179 of the data lines through the contact holes 182. As described above, the contact assistants 81 and 82 may be omitted.

The pixel electrodes 191 are connected to the TFT, thereby receiving the data signals applied thereto via the data lines 171. However, the common electrode 195 is not connected to a switching element such as the TFT. In one exemplary embodiment, the common electrodes 195 may directly receive a signal from an external circuit device.

In such an exemplary embodiment, a common electrode pad 199 connected to the end of the common electrodes 195 where the common electrode liens 193 are commonly connected may be further included. The common electrode pad 199 transmits the signal generated from the external circuit device to the common electrodes 195. Alternative exemplary embodiments include configurations wherein the common electrode pad 199 may be disposed in a location other than that illustrated in FIG. 1.

The common electrodes 195 may be substantially continuously formed along the column direction. That is, the common electrode line 193 is formed on a boundary between the adjacent pixel areas neighboring up and down in a column direction substantially parallel to the data lines. In some configurations the overlapping of the common electrode line 193 and the gate line generates a coupling phenomenon due to the overlapping of the common electrodes 195 on the gate line 121. In an exemplary embodiment of the present invention, a blocking film 88 is formed on the gate line 121 in an area where the gate line 121 and the common electrode lines 193 are vertically aligned to prevent the coupling phenomenon. In one exemplary embodiment, the blocking film 88 may be formed of an organic layer or a floating electrode, e.g., an electrode connected to a floating electric potential. The blocking film 88 may be longitudinally formed according to the direction of the gate line 121, e.g. a direction of extension of the blocking film 88 may be substantially parallel to a direction of extension of the gate line 121.

In one exemplary embodiment, the blocking film 88 may be formed along with the data line 171, and from substantially the same layer as the data line 171. In the exemplary embodiment wherein the blocking film 88 is formed as a floating electrode, the blocking film 88 may be electrically isolated.

In the second display panel 200 facing the first display panel 100, a light blocking member 220 is formed on the second insulation substrate 210, exemplary embodiments of which may be made of transparent glass or other similar materials, similar to the first insulation substrate 110. The light blocking member 220 prevents light leakage, and may have portions corresponding to the gate lines 121 and data lines 171 and the TFT.

In the exemplary embodiment wherein the LCD is a color display, a plurality of color filters 230 are formed on the second insulation substrate 210. A major portion of each of the color filters 230 is disposed in a region enclosed by the light blocking member 220, and may be extended in the longitudinal direction according to the column of the pixel electrodes 191 to overlap the light blocking member 220 as illustrated in FIG. 2. Each of the color filters 230 may represent one of a set of primary colors such as three primary colors of red, green, and blue. Exemplary embodiments also include configurations wherein the color filters 230 are disposed on the first display panel 100.

An overcoat 250 is formed on the color filter 230 and the light blocking member 220. Exemplary embodiments of the overcoat 250 may be made of an inorganic or organic insulator, and the overcoat prevents the color filters 230 from being exposed and provides a planarized surface. Exemplary embodiments include configurations wherein the overcoat 250 may be omitted.

A reference electrode 270 is formed on the overcoat 250. Exemplary embodiments of the reference electrode 270 may be made of a transparent conductor such as ITO or IZO.

The reference electrode 270 may form a vertical electric field with the pixel electrodes 191 applied with the data voltage and the common electrodes 195 applied with the common voltage, however the vertical electric field has a magnitude less than the horizontal electric field “A” generated between the pixel electrodes 191 and the common electrode 195s such that the vertical electric field may have relatively little effect on a degree of liquid crystal rotation.

In one exemplary embodiment, the signal applied to the reference electrode 270 may be a signal having a different voltage level from the signal applied to the common electrodes 195. Alternative exemplary embodiments include configurations wherein the signal applied to the reference electrode 270 may be a voltage having substantially the same level as the signal applied to the common electrodes 195. In one exemplary embodiment, the voltage transmitted to the reference electrode 270 may be uniform.

The reference electrode 270 is formed on the inner surface of the second display panel 200 such that the process to form an additional transparent electrode on the outer surface of the second display panel 200 to improve the static electricity characteristic during manufacturing may be omitted.

Exemplary embodiments include configurations wherein alignment layers (not shown) formed on the inner surfaces of the first display panel 100 and the second display panel 200 may be further included. Also, exemplary embodiments include configurations wherein polarizers (not shown) attached on the outer surfaces of the first display panel 100 and the second display panel 200 may be further included.

As described above, in the present exemplary embodiment the liquid crystal layer 3 has negative dielectric anisotropy. Liquid crystal molecules of the liquid crystal layer 3 are arranged such that a longitudinal axis of the liquid crystal molecules is substantially parallel to the surfaces of the two panels in the configuration wherein an electric field is not applied thereto. In one exemplary embodiment, the liquid crystal layer 3 has dielectric anisotropy of about −2 to about −3.5, and liquid crystal molecules having a rotational viscosity of about 50 mPas to about 120 mPas may be used.

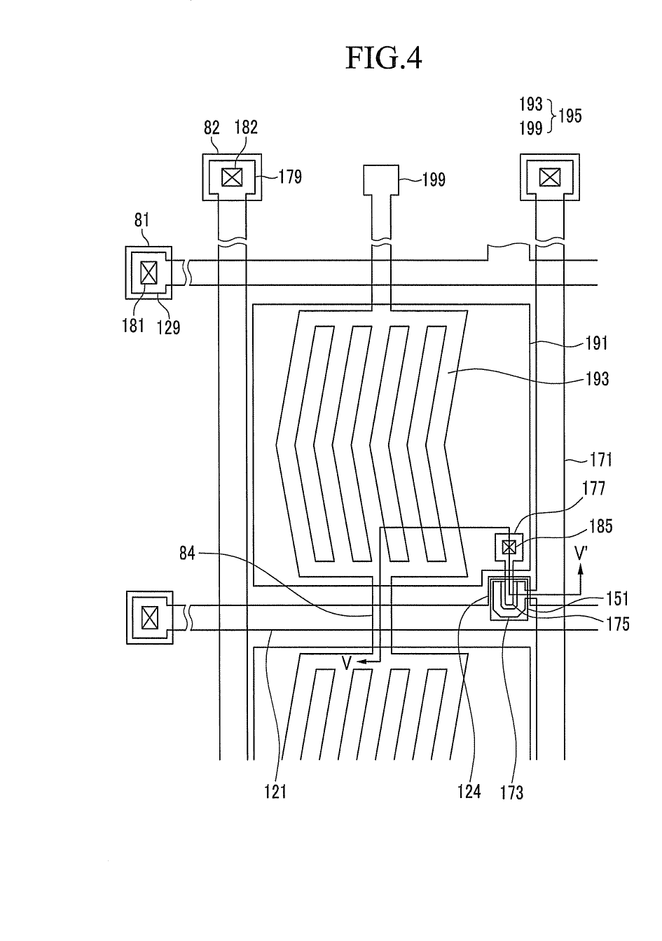

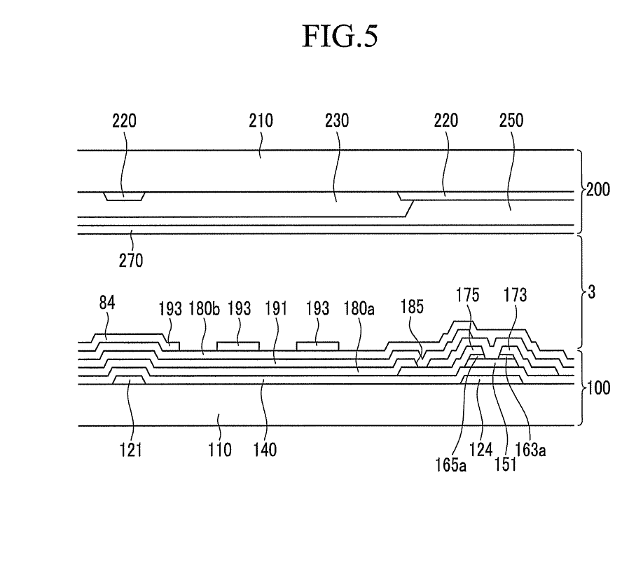

FIG. 4 is a top plan layout view of another exemplary embodiment of a LCD according to the present invention. FIG. 5 is a cross-sectional view taken along line V-V′ of FIG. 4.

The components of the exemplary embodiment of the present invention shown in FIG. 4 and FIG. 5 are similar to those of the exemplary embodiment shown in FIG. 1 to FIG. 3. However, a connecting member 84 connecting the common electrode lines 193 formed in a plurality of pixel areas is added. In one exemplary embodiment, the connecting member 84, which is a portion of the common electrodes 195, is made of the transparent conductive material such as ITO or IZO or other material with similar characteristics.

In one exemplary embodiment, the connecting member 84 may be made with a bar-shaped section that is substantially perpendicular to the gate lines 121 and an extension section which extends substantially parallel to the gate lines 121. Accordingly, an area where the gate line 121 and the common electrodes 195 are overlapped with each other is minimized, thereby reducing the generation of a coupling therebetween.

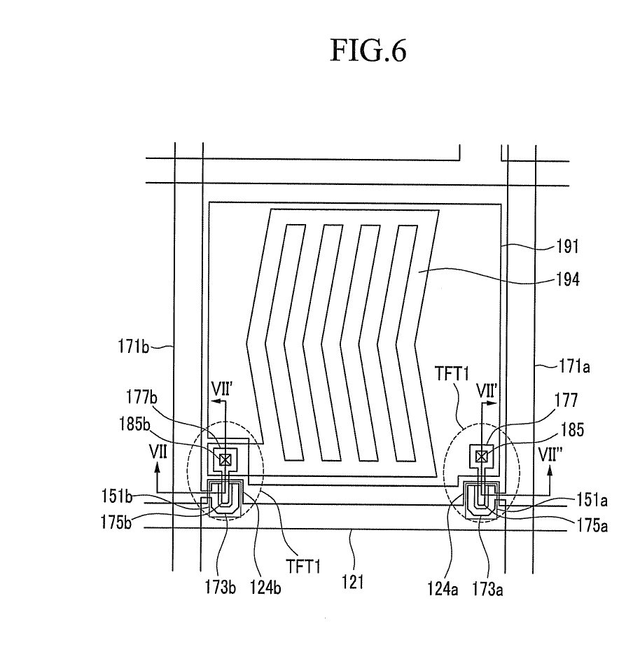

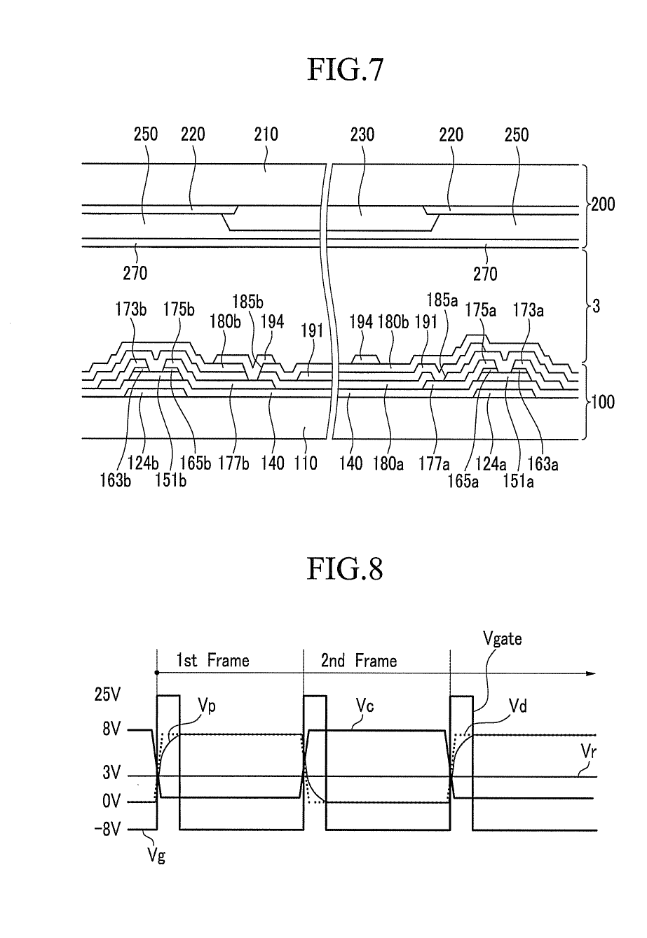

FIG. 6 is a top plan layout view of another exemplary embodiment of an LCD according to the present invention. FIG. 7 is a cross-sectional view taken along line VII-VII′ and line VII′-VII″ of FIG. 6.

An exemplary embodiment shown in FIG. 6 and FIG. 7 includes a plurality of TFTs, i.e., TFT1 and TFT2, in one pixel area, and includes a plurality of data lines, i.e., a first data line 171a and a second data line 171b, for each pixel area, differently from the exemplary embodiments shown in FIG. 1 to FIG. 5. The first ITT TFT1 connected to the pixel electrode 191 has substantially the same structure as that of the ITT of the previous exemplary embodiment.

The second TFT TFT2 is connected to an independent common electrode 194, e.g., a common electrode 194 which is not connected to any other common electrode 194. A data signal applied to the second data line 171b is transmitted to the independent common electrode 194. Differently from the previous exemplary embodiment, in the present exemplary embodiment, each independent common electrode 194 that is separated from each other is formed within each pixel area, and the independent common electrode 194 is connected to the second TFT TFT2. Accordingly, the blocking film 88 shown in FIGS. 1 and 3 and/or the connecting member 84 shown in FIG. 4 may be omitted, and the coupling generated by overlapping the gate line 121 and the independent common electrode 194 is not generated.

Referring to FIG. 6 and FIG. 7, an exemplary embodiment of the present invention will be described in detail.

Similar to the previous exemplary embodiments, a plurality of gate lines 121 extending in the substantially transverse direction are formed on an insulation substrate 110, exemplary embodiments of which may be made of transparent glass, plastic, or other materials having similar characteristics. Each gate line 121 includes a plurality of gate electrodes 124a and 124b that are protruded upward therefrom. A plurality of semiconductor islands 151a and 151b, exemplary embodiments of which may be made of hydrogenated amorphous silicon or polysilicon are formed on the gate insulating layer 140. The semiconductor islands 151a and 151b may be disposed on the gate electrodes 124a and 124b, respectively.

A plurality of ohmic contacts 163a, 165a, 163b, and 165b are formed on the semiconductor islands 151a and 151b. Exemplary embodiments of the ohmic contacts 163a, 165a, 163b, and 165b may be made of a material such as n+hydrogenated amorphous silicon in which an n-type impurity such as phosphorus is doped with high concentration, or of silicide or other materials having similar characteristics. The ohmic contacts 163a, 165a, 163b, and 165b are formed in pairs and are disposed on the semiconductor islands 151a and 151b.

A plurality of data lines, including the first and second data lines 171a and 171b, and a plurality of drain electrodes 175a and 175b are formed on the ohmic contacts 163a, 165a, 163b, and 165b and the gate insulating layer 140. Similar to the previous exemplary embodiment, the data lines 171a and 171b transfer a data signal and are mainly extended in a longitudinal direction, thereby being disposed substantially perpendicularly to the gate lines 121. Each data line 171 includes a plurality of source electrodes 173a and 173b that are extended toward the gate electrode 124a and 124b.

The drain electrodes 175a and 175b are separated from the data lines 171a and 171b and face the source electrode 173a and 173b with respect to the gate electrodes 124a and 124b. In the present exemplary embodiment, each of the drain electrodes 175a and 175b includes one end portion 177a and 177b having a wide area and the other end portion having a bar shape, and the portions of the drain electrodes 175a and 175b with the bar shape are enclosed on at least three sides by the source electrodes 173a and 173b with a “U” shape, respectively.

The first gate electrode 124a, the first source electrode 173a, and the first drain electrode 175a along with the first semiconductor island 151a form the first TFT TFT1, and the channel of the first TFT TFT1 is formed in the first semiconductor 151a between the first source electrode 173a the first drain electrode 175a.

The second gate electrode 124b, the second source electrode 173b, and the second drain electrode 175b along with the second semiconductor island 151b form the second thin film transistor TFT2, and the channel of the second TFT TFT2 is formed in the second semiconductor 151b between the second source electrode 173b and the second drain electrode 175b.

A passivation layer 180a is formed on the data lines 171a and 171b, the drain electrodes 175a and 175b, and the gate insulating layer 140. The passivation layer 180a has first contact holes 185a exposing the drain electrodes 175a.

A plurality of pixel electrodes 191, exemplary embodiments of which may be made of the transparent conductive material such as ITO or IZO are formed on the passivation layer 180a. The pixel electrodes 191 are physically and electrically connected to the drain electrode 175a through the first contact holes 185a, respectively, thereby receiving the data voltage from the drain electrodes 175a.

The pixel electrodes 191 are formed with the island shape in a plurality of pixel areas which includes an area bound by the gate lines 121 and the data lines 171a and 171b. An interlayer insulating layer 180b is formed on the pixel electrodes 191. In one exemplary embodiment, the interlayer insulating layer 180b may be formed on substantially an entire surface of the first insulation substrate 110, and the passivation layer 180a and the interlayer insulating layer 180b have second contact holes 185b passing through them. The second contact holes 185b are disposed on portions where the pixel electrodes 191 and the independent common electrodes 194 are not overlapped. As shown in FIG. 7, the interlayer insulating layer 180b directly covers the upper surface of the passivation layer 180a where the pixel electrodes 191 are not formed, and the second contact holes 185b are continuously passed through the passivation layer 180a and the interlayer insulating layer 180b. Also, in one exemplary embodiment, a portion of the independent common electrode 194 may be protruded to be connected to the second drain electrode 175b through the second contact holes 185b.

As described above, a plurality of independent common electrodes 194 are formed on the interlayer insulating layer 180b. The independent common electrodes 194 are separated from each other, and each of the plurality of common electrodes 194 have a plurality of branch lines extending substantially parallel to each other. Each of the branch lines are separated, however the connection of both ends connects the branch lines into a single independent common electrode 194. Accordingly, the plurality of branch lines transmit substantially the same signal therealong. In one exemplary embodiment, the independent common electrodes 194 may be made of the transparent conductive material such as ITO or IZO.

FIG. 8 is a waveform diagram showing an exemplary embodiment of a driving method of an exemplary embodiment of an LCD according to the present invention.

Referring to FIG. 1 and FIG. 8, a data signal Vd is transmitted by the data line 171 to the pixel electrode 191, and a polarity of the image signal voltage Vp applied to the pixel electrode 191 is periodically changed with reference to the reference voltage 3V. That is, the polarity is changed per frame for the reference potential of the image signal voltage Vp. A polarity of a common voltage Vc applied to the common electrode 195 is also changed per frame unit with reference to the reference voltage 3V. In the present exemplary embodiment, when the image signal voltage Vp is the positive polarity, the common voltage Vc may be the negative polarity, and when the image signal voltage Vp is the negative polarity, the common voltage Vc may be the negative polarity. Similar to the above-described exemplary embodiment, if the image signal voltage Vp and the common voltage Vc are driven while having the opposite polarity for the reference voltage 3V, the driving voltage of the LCD may be reduced as compared to when only an image signal voltage Vp is driven to have an opposite polarity. As described above, a polarity is determined with respect to the reference voltage, e.g., a voltage greater than the reference voltage is referred to as having a positive polarity and a voltage less than the reference voltage is referred to as having a negative polarity.

In the exemplary embodiment shown in FIG. 1 to FIG. 5, the common electrodes 195 are substantially continuously formed in the column direction such that the line inversion is generated.

Referring to FIG. 6 and FIG. 8, the first data signal Vd is transmitted to the pixel electrode 191 by the first data line 171a, and the second data signal Vc is transmitted to the independent common electrode 194 by the second data line 171b. The signal applied to the independent common electrode 194 is not directly transmitted by the external driving device, but is transmitted through the second TFT TFT2 formed in the pixel areas such that dot inversion is possible. In each frame, the signal applied to the pixel electrode 191 and the independent common electrode 194 is driven to be the substantially opposite polarity while inverting per frame unit, similar to the above-described exemplary embodiment. in the present exemplary embodiment, the voltage applied to the pixel electrode 191 and the voltage applied to the independent common electrode 194 may be driven to have substantially the same absolute value. In one exemplary embodiment, the pixel electrode 191 and the voltage applied to the independent common electrode 194 may be driven to have substantially the same absolute value with respect to the reference voltage. That is, the first data signal Vd transmitted to the pixel electrode 191 through the first data line 171a and the second data signal Vc transmitted to the independent common electrode 194 through the second data line 171b may have substantially opposite polarities with reference to the voltage of the reference electrode 270, and may be driven with a voltage of the same absolute value.

Differently from FIG. 8, exemplary embodiments include configurations wherein the reference voltage is not 3V, and may be a different voltage, for example, 0V.

The exemplary embodiment of an LCD according to the present invention is not limited by the above-described driving method, and may be driven by various methods.

According to an exemplary embodiment of the present invention, the liquid crystal layer having the negative dielectric anisotropy is used, and the different signals are applied to the pixel electrode and the common electrode such that the transmittance and the response speed may be simultaneously improved.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A liquid crystal display comprising:
a first substrate;
a gate line disposed on the first substrate;
a data line intersecting the gate line;
a thin film transistor connected to the gate line and the data line;
a pixel electrode connected to the thin film transistor;
an interlayer insulating layer disposed on the pixel electrode;
a common electrode disposed on the interlayer insulating layer and including a plurality of electrically connected common electrode lines extending substantially parallel to each other;
a second substrate disposed substantially opposite to the first substrate;
a reference electrode disposed on substantially an entire surface of the second substrate; and
a liquid crystal layer disposed between the first substrate and the second substrate, wherein the liquid crystal layer has negative dielectric anisotropy.

2. The liquid crystal display of claim 1, wherein the pixel electrode is vertically aligned with the plurality of common electrode lines, and forms a substantially continuous surface throughout an area wherein the pixel electrode and the plurality of common electrode lines are vertically aligned.

3. The liquid crystal display of claim 2, wherein an image signal voltage applied to the pixel electrode and a common voltage applied to the common electrode are inverted with respect to a reference voltage applied to the reference electrode per an individual frame.

4. The liquid crystal display of claim 3, wherein the image signal voltage and the common voltage have opposite polarities with respect to the reference voltage.

5. The liquid crystal display of claim 1, wherein
the thin film transistor includes:
a gate electrode connected to the gate line;
a gate insulating layer disposed on the gate electrode;
a semiconductor layer disposed on the gate insulating layer; and
a source electrode connected to the data line and vertically aligned with the gate electrode and a drain electrode disposed substantially opposite to the source electrode with respect to the gate electrode, and
further comprising a passivation layer disposed on the thin film transistor and having a contact hole, wherein the pixel electrode is connected to the drain electrode through the contact hole.

6. The liquid crystal display of claim 5, further comprising a common electrode pad connected to an end of the common electrode, wherein the common electrode pad transmits a signal applied from an external driving device to the common electrode.

7. The liquid crystal display of claim 6, wherein the common electrode is extended in a direction substantially parallel to a direction of extension of the data line, intersecting the gate line.

8. The liquid crystal display of claim 7, wherein a blocking film is disposed between the gate line and the common electrode.

9. The liquid crystal display of claim 8, wherein the blocking film is made of one of an organic layer and an electrically floating conductor.

10. The liquid crystal display of claim 9, wherein the blocking film is disposed on a substantially same layer as the data line.

11. The liquid crystal display of claim 1, wherein the common electrode further includes a connecting member which connects the plurality of common electrodes, the common electrode having an island shape within an individual pixel.

12. The liquid crystal display of claim 11, further comprising a common electrode pad connected to an end of the common electrode, wherein the common electrode pad transmits a signal applied from an external driving device to the common electrode.

13. The liquid crystal display of claim 1, wherein the liquid crystal layer has dielectric anisotropy of about −2 to about −3.5, and rotation viscosity of about 50 mPas to about 120 mPas.

14. A liquid crystal display comprising:
a first substrate;
a gate line disposed on the first substrate;
a first data line and a second data line intersecting the gate line, and respectively transmitting a first data voltage and a second data voltage;
a first thin film transistor connected to the gate line and the first data line;
a second thin film transistor connected to the gate line and the second data line;
a pixel electrode connected to the first thin film transistor;
an interlayer insulating layer disposed on the pixel electrode;
a common electrode disposed on the interlayer insulating layer, connected to the second thin film transistor, and having a plurality of branch lines electrically connected to each other and extending substantially parallel to each other;
a second substrate disposed substantially opposite to the first substrate;
a reference electrode disposed on substantially an entire surface of the second substrate; and
a liquid crystal layer disposed between the first substrate and the second substrate.

15. The liquid crystal display of claim 14, wherein the pixel electrode is vertically aligned with the plurality of branch lines, and forms a substantially continuous surface throughout an area wherein the pixel electrode and the plurality of branch lines are vertically aligned.

16. The liquid crystal display of claim 15, wherein an image signal voltage applied to the pixel electrode and a common voltage applied to the common electrode are inverted with respect to a reference voltage applied to the reference electrode per an individual frame.

17. The liquid crystal display of claim 16, wherein the image signal voltage and the common voltage have substantially opposite polarities with respect to the reference voltage.

18. The liquid crystal display of claim 17, wherein the pixel electrode is applied with a first data voltage and the common electrode is applied with a second data voltage, and absolute values of the first data voltage and the second data voltage are substantially the same.

19. The liquid crystal display of claim 14, wherein an image signal voltage applied to the pixel electrode and a common voltage applied to the common electrode are inverted with respect to a reference voltage applied to the reference electrode per an individual frame.

20. The liquid crystal display of claim 19, wherein the image signal voltage and the common voltage have substantially opposite polarities with respect to the reference voltage.

21. The liquid crystal display of claim 14, wherein the pixel electrode is applied with a first data voltage and the common electrode is applied with a second data voltage, the first data voltage and the second data voltage have substantially opposite polarities with respect to the reference voltage, and the absolute values of the first data voltage and the second data voltage are substantially the same.
